(19) United States
(12) Patent Application Publication
(10) Pub. No.: US 2023/0252248 A1
(43) Pub. Date: Aug. 10, 2023

(54) APPARATUS OF IN-MEMORY COMPUTING AND METHOD FOR OPERATING SAME

(71) Applicant: Research & Business Foundation SUNGKYUNKWAN UNIVERSITY, Suwon-si (KR)

(72) Inventors: Yoonmyung LEE, Seongnam-si (KR); Eunyoung LEE, Ansan-si (KR)

(73) Assignee: Research & Business Foundation SUNGKYUNKWAN UNIVERSITY, Suwon-si (KR)

(21) Appl. No.: 18/074,863

(22) Filed: Dec. 5, 2022

(30) Foreign Application Priority Data
Feb. 9, 2022 (KR) 10-2022-0016755

(51) Int. Cl. G06G 7/14

(52) U.S. Cl. CPC G06G 7/14

(57) ABSTRACT

Provided are an in-memory computing apparatus and a method for operating the same, and the in-memory computing apparatus according to an embodiment of the present disclosure may include: an input controller provided with an input signal and configured to generate a first input voltage signal, a second input voltage signal, and a third input voltage signal based on the input signal; a weighting value controller configured to generate a first selection signal and a second selection signal based on a weight precision bit number; a memory array provided with the first input voltage signal, the second input voltage signal, and the third input voltage signal from the input controller, and provided with the first selection signal and the second selection signal from the weighting value controller, and configured to generate a first output charge to a seventh output charge based on the first input voltage signal, the second input voltage signal, the third input voltage signal, the first selection signal, and the second selection signal; and an adder provided with the first output charge to the seventh output charge from the memory array and configured to generate a first summation charge to a fourth summation charge based on the weight precision bit number and the first output charge to the seventh output charge.

### CROSS-REFERENCE TO RELATED APPLICATIONS

This application claims the benefit under 35 USC 119(a) of Korean Patent Application No. 10-2022-0016755 filed on Feb. 9, 2022, in the Korean Intellectual Property Office, the entire disclosure of which is incorporated herein by reference for all purposes.

### BACKGROUND OF THE DISCLOSURE

### Field of the Disclosure

The present disclosure relates to an in-memory computing apparatus and a method for operating the same and, more particularly, to an in-memory computing apparatus and a method for operating the same of an electric charge type.

### Related Art

The in-memory computing (IMC) is referred to as a technique of analyzing a massive amount of information in real time without storing the information in a main memory of a server. The in-memory computing may perform a multiply and accumulation (MAC) operation without reading an input and a weighting value, and there is an advantage that a load may be reduced, and may use a several rows simultaneously in performing an MAC operation, and a result value may be obtained without storing an intermediate value.

The in-memory computing operation method may be divided into a current type and an electric charge type. In the current type, a current flows through a bit line depending on the number of activated word lines, and a level of the current may be detected. However, the current type may be vulnerable to a variation of manufacturing, temperature, and voltage. Furthermore, transfer function from MAC result value to current is non-linear, and energy efficiency is low due to continuously flowing current.

The electric charge type has been proposed to compensate the disadvantage of the current type in-memory computing. The electric charge type uses charge sharing of capacitors and may be robust against variations. Furthermore, since the energy may be consumed only by charge/discharge of a capacitor of a predetermined size and a static current does not flow, the energy efficiency may be high. However, there is a problem in that the electric charge type in-memory computing has difficulty in implementing multiple bits.

### SUMMARY OF THE DISCLOSURE

The present disclosure provides a charge type in-memory computing apparatus and a method, which can be implemented for multiple-bit operation.

In an aspect, an in-memory computing apparatus according to an embodiment of the present disclosure may include: an input controller provided with an input signal and configured to generate a first input voltage signal, a second input voltage signal, and a third input voltage signal based on the input signal; a weighting value controller configured to generate a first selection signal and a second selection signal based on a weight precision bit number; a memory array provided with the first input voltage signal, the second input voltage signal, and the third input voltage signal from the input controller, and provided with the first selection signal and the second selection signal from the weighting value controller, and configured to generate a first output charge to a seventh output charge based on the first input voltage signal, the second input voltage signal, the third input voltage signal, the first selection signal, and the second selection signal; and an adder provided with the first output charge to the seventh output charge from the memory array and configured to generate a first summation charge to a fourth summation charge based on the weight precision bit number and the first output charge to the seventh output charge.

In another aspect, a method for operating an in-memory computing apparatus according to an embodiment of the present disclosure may include: generating a first input voltage signal, a second input voltage signal, and a third input voltage signal based on an input signal; generating a first selection signal and a second selection signal based on a weight precision bit number; generating a first output charge to a seventh output charge based on the first input voltage signal, the second input voltage signal, the third input voltage signal, the first selection signal, and the second selection signal; and generating a first summation charge to a fourth summation charge based on the first output charge to the seventh output charge and the weight precision bit number.

In still another aspect, a memory array according to an embodiment of the present disclosure may include: first memory cells arranged in a first column and provided with a first input voltage signal, a second input voltage signal, and a third input voltage signal to generate a first output charge; and second memory cells arranged in a second column to a fourth column and provided with the first input voltage signal, the second input voltage signal, the third input voltage signal, a first weighting value selection signal, and a second weighting value selection signal to generate a second output charge to a seventh output charge, wherein the first memory cell includes a first static random access memory (SRAM) for storing a sign of a weighting value and a second SRAM for storing a size of the weighting value, and wherein the second memory cell includes a third SRAM for storing either one of a sign or a size of the weighting value and a fourth SRAM for storing a size of the weighting value.

According to the present disclosure, a size of the capacitor in a memory cell is minimized, and the linearity of the in-memory computing of an electric charge type can be maintained, and accordingly, an implementation of multiple bits can be available.

According to the present disclosure, in the case of performing the same operation, the power consumption can be decreased in comparison with the conventional digital type, and the operation speed can be increased.

### BRIEF DESCRIPTION OF THE DRAWINGS

The accompanying drawings included in the present application to further understand the present disclosure and constructing a part thereof illustrate the embodiment of the present disclosure together with the detailed description that describes the principle of the present disclosure.

FIG. 1 is a conceptual diagram illustrating an in-memory computing apparatus according to an embodiment of the present disclosure.

FIG. 2 is a conceptual diagram illustrating a bank according to an embodiment of the present disclosure.

FIG. 3 is a circuit diagram of the first memory cell according to an embodiment of the present disclosure.

FIG. 4 is a conceptual diagram illustrating the third input voltage signal according to an embodiment of the present disclosure.

FIG. 5 is a conceptual diagram illustrating a sampling signal according to an embodiment of the present disclosure.

FIG. 6 is a circuit diagram illustrating the second memory cell according to an embodiment of the present disclosure.

FIG. 7 is a conceptual diagram illustrating a connection relationship between memory cells according to an embodiment of the present disclosure.

FIG. 8 is a circuit diagram illustrating the adder according to an embodiment of the present disclosure.

FIGS. 9 to 11 are circuit diagrams illustrating the adder according to the weight precision bit number.

FIG. 12 is a flowchart illustrating an operation method of an in-memory computing apparatus according to an embodiment of the present disclosure.

FIGS. 13 to 15 are conceptual diagrams illustrating the effect of the present disclosure.

### DESCRIPTION OF EXEMPLARY EMBODIMENTS

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated. In general, suffixes such as “module” and “unit” may be used to refer to elements or components. Use of such suffixes herein is merely intended to facilitate description of the specification, and the suffixes do not have any special meaning or function. In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents, and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “electrically connected with” or “connected with” another element, there may be intervening elements present. In contrast, it will be understood that when an element is referred to as being “directly and electrically connected with” or “connected with” another element, there are no intervening elements present.

A singular representation may include a plural representation unless context clearly indicates otherwise.

In the following description, it should be understood that the term such as “include” or “have” is designed to designate the presence of a property, a figure, a step, an operation, an element, a component, or the combination thereof, and does not preclude a possibility of the presence of one or more other features or addition to the property, the figure, the step, the operation, the element, the component, or the combination thereof.

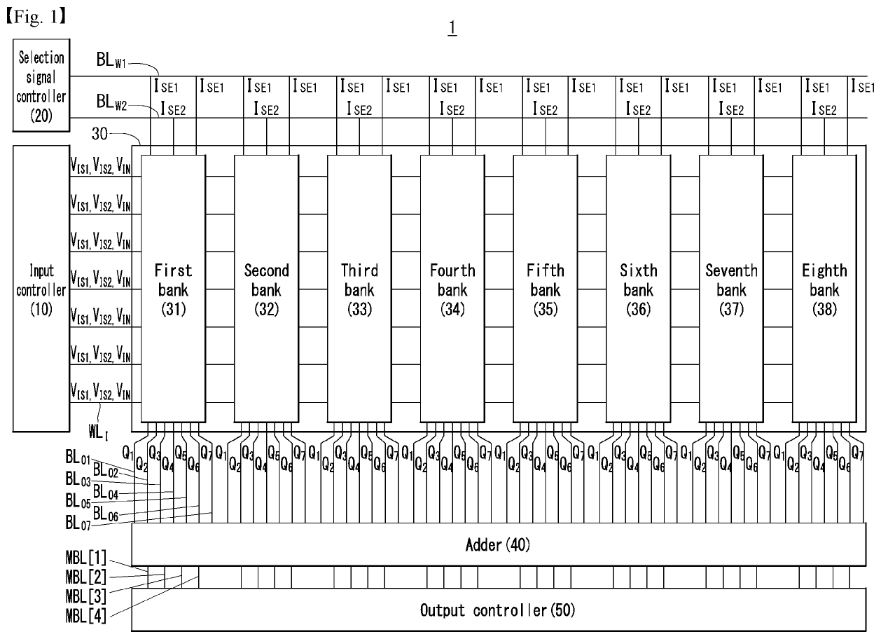

FIG. 1 is a conceptual diagram illustrating an in-memory computing apparatus according to an embodiment of the present disclosure.

Referring to FIG. 1, an in-memory computing apparatus 1 according to an embodiment of the present disclosure may include an input controller 10, a selection signal controller 20, a memory array 30, an adder 40, and an output controller 50.

The input controller 10 may be connected to the memory array 30 through an input word line WU. The input controller 10 may be provided with a digital voltage from the exterior. The input controller 10 may perform a processing for the digital voltage and generate a first input voltage signal V_{IS1}, a second input voltage signal V_{IS2}, and a third input voltage signal V_{IN}. Here, the first input voltage signal V_{IS1} may represent a sign of an input signal, and the second input voltage signal V_{IS2} may be a signal of which magnitude is the same as that of the first input voltage signal V_{IS1} and the sign is opposite to that of the first input voltage signal V_{IS1}. The third input voltage signal V_{IN} may represent a magnitude of the input signal. For example, the input controller 10 may include a digital-to-analog converter (DAC) and a buffer.

The input controller 10 may provide the first input voltage signal V_{IS1}, the second input voltage signal V_{IS2}, and the third input voltage signal V_{IN} to the memory array 30. The input controller 10 may provide the first input voltage signal V_{IS1}, the second input voltage signal V_{IS2}, and the third input voltage signal V_{IN} to the memory array 30 through the input word line WL_{I}. In the present disclosure, it is shown that there are 8 input word lines WL_{I}, but this is just an example, and the present disclosure is not limited thereto.

The selection signal controller 20 may generate a first selection signal I_{SE1} and a second selection signal I_{SE2}. For example, the first selection signal I_{SE1} and the second selection signal I_{SE2} may be 2-bit signals and may be either one of [1, 0] or [0, 1]. The selection signal controller 20 may provide a weighting value to the memory array 30. The selection signal controller 20 may provide the first selection signal I_{SE1} to the memory array 30 through a first selection signal bit line BL_{SE1} and provide the second selection signal I_{SE2} to the memory array through a second selection signal bit line BL_{SE2}.

The memory array 30 may include a first bank 31 to an eighth bank 38. In the present disclosure, it is shown that the memory array 30 includes the first bank 31 to the eighth bank 38, but this is just an example, and the memory array 30 may include the more banks. The first bank 31 to the eighth bank 38 may be identically configured. The first bank 31 to the eighth bank 38 may be reciprocally connected with each other through the input word line WU. Each of the first bank 31 to the eighth bank 38 may be provided with the first input voltage signal V_{IS1}, the second input voltage signal V_{IS2}, and the third input voltage signal V_{IN} from the input controller 10. Each of the first bank 31 to the eighth bank 38 may be provided with the first selection signal I_{SE1} and the second selection signal I_{SE2} from the selection signal controller through the first selection signal bit line BL_{SE1} and second selection signal bit line BL_{SE2}. Each of the first bank 31 to the eighth bank 38 may be provided with two first selection signals I_{SE1} and one second selection signal I_{SE2}.

Each of the first bank 31 to the eighth bank 38 may generate a first output charge Q₁ to a seventh output charge Q₇ based on the first input voltage signal V_{IS1}, the second input voltage signal V_{IS2}, and the third input voltage signal V_{IN}, and the first selection signal I_{SE1} and the second selection signal I_{SE2}. Each of the first bank 31 to the eighth bank 38 may provide the first output charge Q₁ to the seventh output charge Q₇ to the adder 40.

The adder 40 may be provided with the first output charge Q₁ to the seventh output charge Q₇ from the memory array 30. The adder 40 may be provided with the first output charge Q₁ to the seventh output charge Q₇ from each of the first bank 31 to the eighth bank 38. The adder 40 may perform addition for the first output charge Q₁ to the seventh output charge Q₇ and generate a first addition charge MBL [1] to a fourth addition charge MBL [4]. The adder 40 may provide the first addition charge MBL [1] to the fourth addition charge MBL [4] to the output controller 50.

The output controller 50 may be provided with the first addition charge MBL [1] to the fourth addition charge MBL [4] from the adder 40. The output controller 50 may generate an output voltage based on the first addition charge MBL [1] to the fourth addition charge MBL [4]. The output controller 50 may generate an analog voltage based on the first addition charge MBL [1] to the fourth addition charge MBL [4]. The output controller 50 may generate an output voltage by converting the analog voltage to a digital voltage.

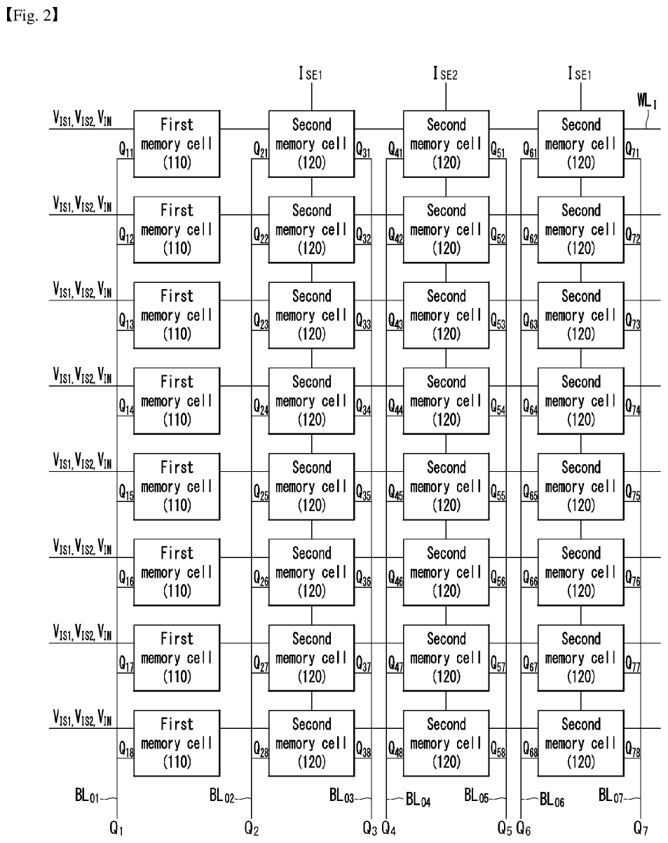

FIG. 2 is a conceptual diagram illustrating a bank according to an embodiment of the present disclosure.

Referring to FIG. 2, a bank 100 may be identically configured with the first bank 31 to the eighth bank 38 shown in FIG. 1. The bank 100 may include a plurality of first memory cells 110 and a plurality of second memory cells 120.

The first memory cells 110 may be arranged in a first column of the bank 100. 8 first memory cells 110 may be arranged in the first column. The second memory cells 120 may be arranged in a second column to a fourth column. 8 second memory cells 120 are respectively arranged in the second column to the fourth column. Among the first memory cells 110 and the second memory cells 120, the first memory cell 110 and the second memory cell 120 arranged in the same column may be reciprocally connected with each other through the same input word line WL_{I}, and may be provided with the first input voltage signal V_{IS1}, the second input voltage signal V_{IS2}, and the third input voltage signal V_{IN} from the input controller 10.

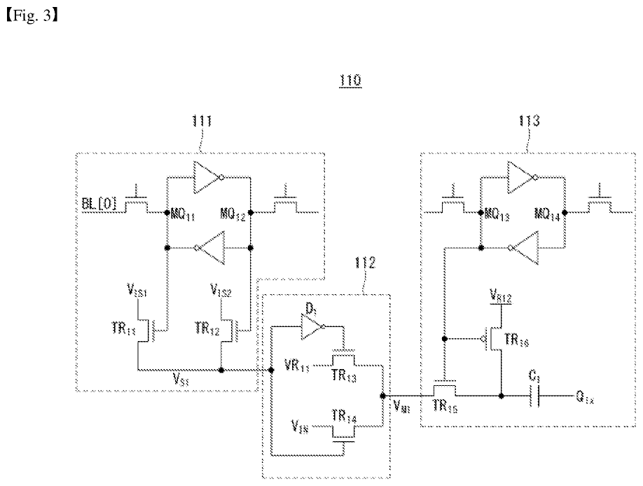

Each of the first memory cells 110 may generate a first operation charge based on the first input voltage signal V_{IS1} and the second input voltage signal V_{IS2}. The first output charge may include a first-1 operation charge Q₁₁ to a first-7 operation charge Q₁₇. This will be described in detail with reference to FIG. 3 to FIG. 5.

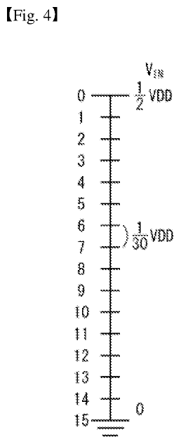

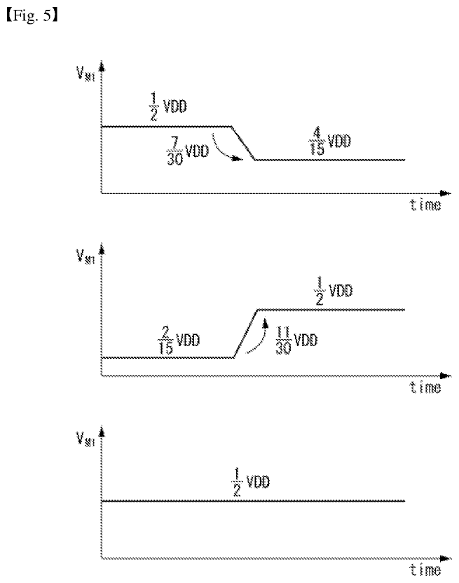

FIG. 3 is a circuit diagram of the first memory cell according to an embodiment of the present disclosure. FIG. 4 is a conceptual diagram illustrating the third input voltage signal according to an embodiment of the present disclosure. FIG. 5 is a conceptual diagram illustrating a sampling signal according to an embodiment of the present disclosure.

Referring to FIG. 3 to FIG. 5, the first memory cell 110 according to an embodiment of the present disclosure may be a 2-bit circuit. A weighting value may be prestored in the first memory cell 110, and a first threshold voltage signal may be pre-charged. The first threshold voltage signal may include a first-1 threshold voltage signal VR₁₁ and a first-2 threshold voltage signal VR₁₂.

The first memory cell 110 may include a sign determinator 111, a multiplexer 112, and an output generator 113. The first input voltage signal V_{IS1} and the second input voltage signal V_{IS2} may be applied to the sign determinator 111. The first input voltage signal V_{IS1} may represent a sign of the input signal. The first input voltage signal V_{IS1} may include either one of a first waveform or a second waveform. The first waveform may be a waveform shifted from 0 to 1, and the second waveform may be a waveform shifted from 1 to 0. In the case that the first input voltage signal V_{IS1} include the first waveform, a sign of the input signal may be a positive sign, and in the case that the first input voltage signal V_{IS1} include the second waveform, a sign of the input signal may be a negative sign.

The second input voltage signal V_{IS2} may be a signal having an opposite waveform to the first input voltage signal V_{IS1} In the case that the first input voltage signal V_{IS1} includes the first waveform, the second input voltage signal V_{IS2} may include the second waveform, and in the case that the first input voltage signal V_{IS1} includes the second waveform, the second input voltage signal V_{IS2} may include the first waveform. The sign determinator 111 may use either one of the first input voltage signal V_{IS1} or the second input voltage signal V_{IS2} and generate a first sign signal V_{S1}.

The sign determinator 111 may include a first-1 SRAM circuit SR₁₁ and a first-1 transistor TR₁₁, and a first-2 transistor TR₁₂. A first weighting value may be applied to the first-1 SRAM circuit SR₁₁. The first weighting value may include a first-1 weighting value MQ₁₁ and a first-2 weighting value MQ₁₂. Here, the first-1 weighting value MQ₁₁ may represent a sign of the weighting value, and the first-2 weighting value MQ₁₂ may be a value opposite to the first-1 weighting value MQ₁₁. Here, the weighting value may be a value prestored in the first memory cell 110. For example, in the case that a sign of the weighting value is a positive sign, the first-1 weighting value MQ₁₁ may be 0, and the first-2 weighting value MQ₁₂ may be 1. In the case that a sign of the weighting value is a negative sign, the first-1 weighting value MQ₁₁ may be 1, and the first-2 weighting value MQ₁₂ may be 0.

In the case that the first-1 weighting value MQ₁₁ is 1, and the first-2 weighting value MQ₁₂ is 0, the first-1 transistor TR₁₁ may be turned on, and first-2 transistor TR₁₂ may be turned off. In this case, the first input voltage signal V_{IS1} may be applied to the sign determinator 111, and may generate first sign signal V_{S1} based on the first input voltage signal V_{IS1} and the first-1 weighting value MQ₁₁. In the case that the first-1 weighting value MQ₁₁ is 0, and the first-2 weighting value MQ₁₂ is 1, the first-1 transistor TR₁₁ may be turned off, and first-2 transistor TR₁₂ may be turned on. The second input voltage signal V_{IS2} may be applied to the sign determinator 111, and may generate the first sign signal V_{S1} based on the second input voltage signal V_{IS2} and the first-2 weighting value MQ₁₂. The sign determinator 111 may provide the first sign signal V_{S1} to the multiplexer 112.

The multiplexer 112 may be provided with the first sign signal V_{S1} from the sign determinator 111. The first-1 threshold voltage signal VR₁₁ and the third input voltage signal V_{IN} may be applied to the multiplexer 112. Here, a magnitude of the first-1 threshold voltage signal VR₁₁ may be ½ VDD. The third input voltage signal V_{IN} may be a value of a magnitude between V_{SS} and the first-1 threshold voltage signal VR₁₁. The third input voltage signal V_{IN} may have an analog value and may be between 0 to 15, thereby distinguished by 16 steps. For example, in the case that Vss is 0 and the magnitude of the first-1 threshold voltage signal VR₁₁ is ½ VDD, the third input voltage signal V_{IN} of the first step may be 1/30 VDD. The multiplexer 112 may generate a first sampling signal V_{M1} based on the first sign signal V_{S1}, the first-1 threshold voltage signal VR₁₁, and the third input voltage signal V_{IN}.

The multiplexer 112 may include a first diode D₁, a first-3 transistor TR₁₃, and a first-4 transistor TR₁₄. The first-1 threshold voltage signal VR₁₁ may be applied to the first-3 transistor TR₁₃, and the third input voltage signal V_{IN} may be applied to the first-4 transistor TR₁₄. The first sign signal V_{S1} may be applied to the first-3 transistor TR₁₃ and the first-4 transistor TR₁₄. Here, the first sign signal V_{S1} may be rectified by the first diode D₁.

The multiplexer 112 may determine a waveform of the first sampling signal V_{M1} based on the first sign signal V_{S1}. In the case that the first sign signal V_{S1} includes a first waveform, the multiplexer 112 may determine a waveform of the first sampling signal V_{M1} to the first waveform, and in the case that the first sign signal V_{S1} includes a second waveform, the multiplexer 112 may determine a waveform of the first sampling signal V_{M1} to the second waveform. Here, the first waveform may have a form having a magnitude of an initial value of a magnitude of the first-1 threshold voltage signal VR₁₁ and may be decreasing by a magnitude of the third input voltage signal V_{IN}. The second waveform may have a form increasing from an initial value by a magnitude of the third input voltage signal V_{IN} and converge to a magnitude of the first-1 threshold voltage signal VR₁₁.

For example, as shown in FIG. 5(a), in the case that an input signal is +0111₍₂₎ and a weighting value is −1, the first sign signal V_{S1} may have the first waveform. Accordingly, the multiplexer 112 may generate the first sampling signal V_{M1} having a form converged to 4/15 VDD which is decreasing by a magnitude of the third input voltage signal V_{IN} from ½ VDD, which is a magnitude of the first-1 threshold voltage signal VR₁₁.

As shown in FIG. 5(b), in the case that an input signal is −1011₍₂₎ and a weighting value is −1, the first sign signal V_{S1} may have the second waveform. Accordingly, the multiplexer 112 may generate the first sampling signal V_{M1} having a form converged to ½ VDD which is increasing by 11/30 VDD, a magnitude of the third input voltage signal V_{IN} from an initial value. As shown in FIG. 5(c), in the case that an input signal is 0000₍₂₎ and a magnitude of the third input voltage signal V_{IN} is 0, the first sampling signal V_{M1} may be ½ VDD. The multiplexer 112 may provide the first sampling signal V_{M1} to the output generator 113.

Meanwhile, the values of the first sign signal V_{S1} and the first sampling signal V_{M1} generated based on the waveforms of the first input voltage signal V_{IS1} and the second input voltage signal V_{IS2}, the first-1 weighting value MQ₁₁ is 0, and the first-2 weighting value MQ₁₂ may be as arranged in Table 1 below.

TABLE 1

| Sign of | +(0) | | −(1) | |
|---|---|---|---|---|
| input | | | | |
| signal | | | | |
| Waveform of first input current signal | 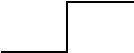 | | 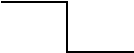 | |
| Waveform of second input current signal | 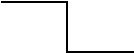 | | 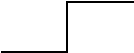 | |
| First-1 | +(0) | −(1) | +(0) | −(1) |
| weighting | | | | |
| value | | | | |

| | | | |
|---|---|---|---|
| Weighting | + | − | + |
| value sign | | | |
| First sampling signal | 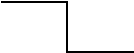 | 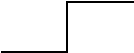 | 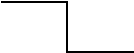 |
| Change of first sampling | ${V}_{IN} \to \frac{1}{2} VDD$ | $\frac{1}{2} VDD \to \frac{1}{2} VDD - {V}_{IN}$ | ${V}_{IN} \to \frac{1}{2} VDD$ |

The output generator 113 may be provided with the first sampling signal V_{M1} from the multiplexer 112. The first-2 threshold voltage signal VR₁₂ may be applied to the output generator 113. A magnitude of the first-2 threshold voltage signal VR₁₂ may be VDD.

The output generator 113 may generate a first operation charge Q_{1X} through either one of the first sampling signal V_{M1} and the first-2 threshold voltage signal VR₁₂. The first operation charge Q_{1X} may be either one of the first-1 operation charge Q₁₁ to the first-7 operation charge Q₁₇.

The output generator 113 may include a first-2 SRAM portion SR₁₂, a first-5 transistor T_{R15}, a first-6 transistor T_{R16}, and a first capacitor C₁. A magnitude of the first capacitor C₁ may be X. The first-2 SRAM portion SR₁₂ may include a first-3 weighting value MQ₁₃ and a first-4 weighting value MQ₁₄. Here, the first-3 weighting value MQ₁₃ may represent a size of the weighting value, and the first-4 weighting value MQ₁₄ may be a value opposite to the first-3 weighting value MQ₁₃. Here, the weighting value may be a value prestored in the first memory cell 110. For example, in the case that a size of the weighting value is 1, the first-3 weighting value MQ₁₃ may be 1, and the first-4 weighting value MQ₁₄ may be 0. In the case that a size of the weighting value is 0, the first-3 weighting value MQ₁₃ may be 0, and the first-4 weighting value MQ₁₄ may be 1.

In the case that the first-3 weighting value MQ₁₃ is 1 and the first-4 weighting value MQ₁₄ is 0, the first-5 transistor T_{R15} may be turned on, and the first-6 transistor T_{R16} may be turned off. In this case, the first sampling signal V_{M1} may be applied to the first capacitor C₁, and the first operation charge Q_{1X} may be charged based on the first sampling signal V_{M1}.

In the case that the first-3 weighting value MQ₁₃ is 0 and the first-4 weighting value MQ₁₄ is 1, the first-5 transistor T_{R15} may be turned off, and the first-6 transistor T_{R16} may be turned on. In this case, the first-2 threshold voltage signal VR₁₂ may be applied to the first capacitor C₁, and the first operation charge Q_{1X} may be charged based on the first-2 threshold voltage signal VR₁₂. In such a way, the first memory cell 110 may generate the first operation charge Q_{1X}.

Referring to FIG. 2 again, each of the first memory cells 110 may generate the first-1 operation charge Q₁₁ to a first-8 operation charge Q₁₈. The bank 100 may provide the first output charge Q₁ summing the first-1 operation charge Q₁₁ to the first-8 operation charge Q₁₈ to the adder 40 through a first output bit line BL₀₁.

Each of the second memory cells 120 may be provided with either one of the first selection signal I_{SE1} and the second selection signal I_{SE2} from the selection signal controller 20. Among the second memory cells 120, the second memory cells 120 arranged in the same second column and the fourth column may be provided with the first selection signal I_{SE1}, and the second memory cells 120 arranged in the third column may be provided with the second selection signal I_{SE2}.

The second memory cells 120 may generate an output charge based on one of the first input voltage signal V_{IS1}, the second input voltage signal V_{IS2}, the first selection signal I_{SE1}, and the second selection signal I_{SE2}. The second memory cells 120 arranged in the second column may generate a second operation charge Q_{2X} to a seventh operation charge Q_{7X} based on the first input voltage signal V_{IS1}, the second input voltage signal V_{IS2}, and the first selection signal I_{SE1}. The second operation charge Q_{2X} may include a second-1 operation charge Q₂₁ to a second-8 operation charge Q₂₈, and a third operation charge Q_{3X} may include a third-1 operation charge Q₃₁ to a third-8 operation charge Q₃₈.

The second memory cells 120 arranged in the third column may generate a fourth operation charge Q_{4X} to a fifth operation charge Q_{5X} based on the first input voltage signal V_{IS1}, the second input voltage signal V_{IS2}, and the second selection signal I_{SE2}. The fourth operation charge Q_{4X} may include a fourth-1 operation charge Q₄₁ to a fourth-8 operation charge Q₄₈, and the fifth operation charge Q_{5X} may include a fifth-1 operation charge Q₅₁ to a fifth-8 operation charge Q₅₈.

The second memory cells 120 arranged in the fourth column may generate a sixth operation charge Q_{6X} to a seventh operation charge Q_{7X} based on the first input voltage signal V_{IS1}, the second input voltage signal V_{IS2}, and the first selection signal I_{SE1}. The sixth operation charge Q_{6X} may include a sixth-1 operation charge Q₆₁ to a sixth-8 operation charge Q₆₈, and the seventh operation charge Q_{7X} may include a seventh-1 operation charge Q₇₁ to a seventh-8 operation charge Q₇₈. This will be described in detail as below.

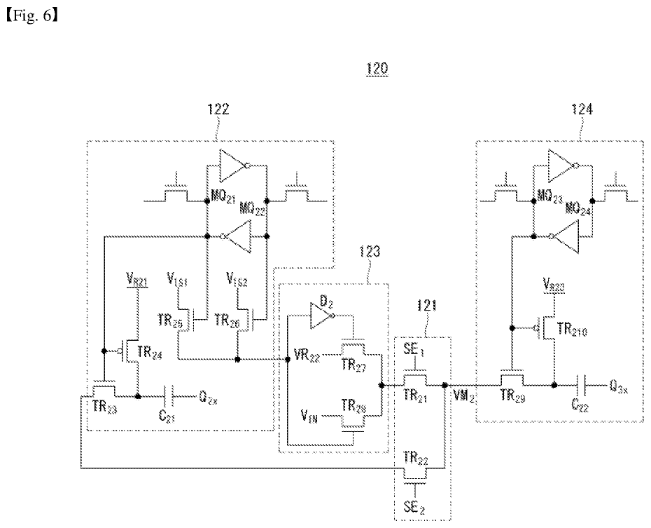

FIG. 6 is a circuit diagram illustrating the second memory cell according to an embodiment of the present disclosure.

Referring to FIG. 6, the second memory cell 120 according to an embodiment of the present disclosure may include a signal selector 121, a first output generator 122, a multiplexer 123, and a second output generator 124. A second threshold voltage signal may be pre-charged in the second memory cell 120. The second threshold voltage signal may include a second-1 threshold voltage signal VR₂₁ to a second-3 threshold voltage signal VR₂₃.

The signal selector 121 may include a second-1 transistor TR₂₁ and a second-2 transistor TR₂₂. The signal selector 121 may be provided with a selection signal from the selection signal controller 20. The selection signal may be either one of the first selection signal I_{SE1} or the second selection signal I_{SE2}. For example, in the case that the second memory cell 120 is arranged in the second column or the fourth column, the selection signal may be the first selection signal I_{SE1}, and in the case that the second memory cell 120 is arranged in the third column, the selection signal may be the second selection signal I_{SE2}.

The selection signal may have a first selection value SE₁ and a second selection value SE₂. The second selection value SE₂ may be opposite to the first selection value SE₁. In the case that the first selection value SE₁ is 1, the second selection value SE₂ may be 0, and in the case that the first selection value SE₁ is 0, the second selection value SE₂ may be 1.

In the case that the first selection value SE₁ is 1 and the second selection value SE₂ is 0, the second-1 transistor TR₂₁ may be turned on, and the second-2 transistor TR₂₂ may be turned off. This case may be defined that the second memory cell 120 operates in a first mode. In the case that the first selection value SE₁ is 0 and the second selection value SE₂ is 1, the second-1 transistor TR₂₁ may be turned off, and the second-2 transistor TR₂₂ may be turned on. This case may be defined that the second memory cell 120 operates in a second mode.

The first output generator 122 may include a second-1 SRAM circuit SR₂₁, a second-3 transistor TR₂₃ to a second-7 transistor TR₂₇, and a second-1 capacitor C₂₁. A magnitude of the second-1 capacitor C₂₁ may be 2×. The first output generator 122 may include a second-1 weighting value MQ₂₁ and a second-2 weighting value MQ₂₂. In the case that the second memory cell 120 operates in the first mode, the second-1 weighting value MQ₂₁ and the second-2 weighting value MQ₂₂ may represent a sign of a weighting value. In the case that the second memory cell 120 operates in the second mode, the second-1 weighting value MQ₂₁ and the second-2 weighting value MQ₂₂ may represent a size of a weighting value.

In the case that the second memory cell 120 operates in the first mode, the second-3 transistor TR₂₃ may not be turned on, and the second-4 transistor TR₂₄ may be turned on. The second-1 threshold voltage signal VR₂₁ may be applied to the second-1 capacitor C₂₁, and the second operation charge Q2X may be charged based on the second-1 threshold voltage signal VR21. In addition, the second-5 transistor TR₂₅ and the second-6 transistor TR₂₆ may be turned on, and the first output generator 122 may operate in the same way as the output determinator 111. Accordingly, the first output generator 122 may generate a second sign signal based on the first input voltage signal V_{IS1}, the second input voltage signal V_{IS2}, the second-1 weighting value MQ21, and the second-2 weighting value MQ22. The first output generator 122 may provide the second sign signal to the multiplexer 123.

In the case that the second memory cell 120 operates in the second mode, the second-3 transistor TR₂₃ may be turned on, and the second-4 transistor TR₂₄ to the second-7 transistor TR₂₇ may be turned off. The first output generator 122 may generate a second sampling signal V_{M2}. The second sampling signal V_{M2} may be applied to the second-1 capacitor C₂₁, and the second operation charge Q_{2X} may be charged based on the second sampling signal V_{M2}. Furthermore, the first output generator 122 may provide the second sampling signal V_{M2} to the second output generator 124.

The multiplexer 123 may include a second diode D₂, a second-7 transistor TR₂₇, and a second-8 transistor TR₂₈. In the case that the second memory cell 120 operates in the first mode, the multiplexer 123 may operate in the same way as the multiplexer 112 shown in FIG. 3. The multiplexer 123 may be provided with the second sign signal from the first output generator 122. The multiplexer 123 may generate the second sampling signal V_{M2} based on the second sign signal and provide the second sampling signal V_{M2} to the second output generator 124 through the weighting value selector 121. In the case that the second memory cell 120 operates in the second mode, the multiplexer 123 may not operate.

The second output generator 124 may be identically constructed to the output generator 124 of the first memory cell 110. The second output generator 124 may include a second-2 SRAM circuit SR₂₂, a second-7 transistor TR₂₇, a second-8 transistor TR₂₈, and a second-2 capacitor C₂₂. A magnitude of the second-2 capacitor C₂₂ may be X or a half of that of the second-1 capacitor C₂₁. The second output generator 124 may include a second-3 weighting value MQ₂₃ and a second-4 weighting value MQ₂₄. Here, the second-3 weighting value MQ₂₃ may represent a size of a weighting value, and the second-4 weighting value MQ₂₄ may be opposite to the second-3 weighting value MQ₂₃.

In the case that the second-3 weighting value MQ₂₃ is 1 and the second-4 weighting value MQ₂₄ is 0, a second-9 transistor TR₂₉ may be turned on, and a second-10 transistor TR₂₁₀ may be turned off. In this case, the second sampling signal V_{M2} may be applied to the second-2 capacitor C₂₂, and a third operation charge Q_{3X} may be charged.

In the case that the second-3 weighting value MQ₂₃ is 0 and the second-4 weighting value MQ₂₄ is 1, a second-9 transistor TR₂₉ may be turned off, and a second-10 transistor TR₂₁₀ may be turned on. In this case, a second-3 threshold signal VR₂₃ may be applied to the second-2 capacitor C₂₂, and the third operation charge Q_{3X} may be charged. In such a way, the second memory cell 120 may generate the second operation charge Q_{2X} and the third operation charge Q_{3X}. In the present disclosure, the second memory cell 120 arranged in the second column is mainly described, but the second memory cell 120 arranged in the third column and the fourth column may identically operate. The second memory cell 120 arranged in the third column may generate a fourth operation charge Q_{4X} and a fifth operation charge Q_{5X}, and the second memory cell 120 arranged in the fourth column may generate a sixth operation charge Q_{6X} and a seventh operation charge Q_{7X}.

The connection relationship between the second memory cells 120 and the weighting value bit number of the bank 100 may be changed depending on whether the second-1 weighting value MQ₂₁ and the second-2 weighting value MQ₂₂ of the memory cell 120 arranged in the second column to the fourth column represent a sign of a weighting value. This will be described in detail as below.

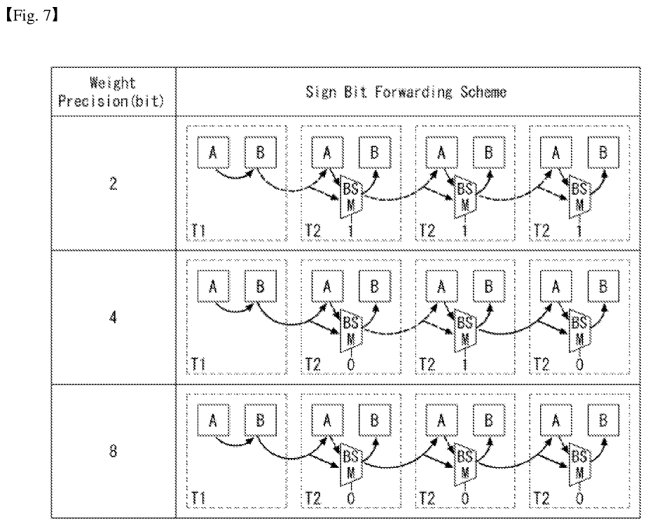

FIG. 7 is a conceptual diagram illustrating a connection relationship between memory cells according to an embodiment of the present disclosure.

Referring to FIG. 7, T1 may be the first memory cell, and T2 may be the second memory cell. The weight precision bit number of the bank 100 may be one of 2, 4, and 8. In the case that the first selection signal is provided to the second memory cells 120 arranged in the second column and the fourth column and the second selection signal is provided to the second memory cells 120 arranged in the third column, the weight precision bit number may be as represented in Table 2 below.

TABLE 2

| | First selection | Second selection |
|---|---|---|
| | signal (I_{SE1}) | signal (I_{SE2}) |
| Weight precision | [1, 0] | [1, 0] |
| bit number = 2 | | |
| Weight precision | [0, 1] | [1, 0] |
| bit number = 4 | | |
| Weight precision | [0, 1] | [0, 1] |
| bit number = 8 | | |

In the case that the first selection signal I_{SE1} and the second selection signal I_{SE2} are [1, 0], respectively, the second-1 weighting value MQ₂₁ and the second-2 weighting value MQ₂₂ of the second memory cell 120 arranged in the second column to the fourth column may represent a sign of a weighting value. In this case, the weight precision bit number of each of the second memory cells 120 arranged in the second column to the fourth column may be 2.

In the case that the first selection signal I_{SE1} is [0, 1] and the second selection signal I_{SE2} is [1, 1], the second-1 weighting value MQ₂₁ and the second-2 weighting value MQ₂₂ of the second memory cell 120 arranged in the second column to the fourth column may represent a size of a weighting value. The second-1 weighting value MQ₂₁ and the second-2 weighting value MQ₂₂ of the second memory cell 120 arranged in the third column may represent a sign of a weighting value. In this case, the second memory cell 120 arranged in the second column may be provided with a sign of a weighting value from the first memory cells 110, and the weight precision bit number of the first memory cells 110 and the second memory cell 120 arranged in the second column may be 4. The second memory cell 120 arranged in the fourth column may be provided with a sign of a weighting value from the second memory cell 120 arranged in the third column, and the weight precision bit number of the second memory cell 120 arranged in the third column and the fourth column may be 4.

In the case that the first selection signal I_{SE1} and the second selection signal I_{SE2} are [0, 1], respectively, the second-1 weighting value MQ₂₁ and the second-2 weighting value MQ₂₂ of the second memory cell 120 arranged in the second column to the fourth column may represent a size of a weighting value. In this case, the second memory cell 120 arranged in the second column to the fourth column may be provided with a sign of a weighting value from the first memory cells 110, and the weight precision bit number of the first memory cells 110 and the second memory cell 120 arranged in the second column may be 8.

Referring to FIG. 2 again, the bank 100 may generate the first output charge Q₁ to the seventh output charge Q₇. Here, the first output charge Q₁ may be a summation of the first-1 operation charge Q₁₁ to the first-8 operation charge Q₁₈, and the second output charge Q₂ may be a summation of the second-1 operation charge Q₂₁ to the second-8 operation charge Q₂₈, the third output charge Q₃ may be a summation of the third-1 operation charge Q₃₁ to the third-8 operation charge Q₃₈, the fourth output charge Q₄ may be a summation of the fourth-1 operation charge Q₄₁ to the fourth-8 operation charge Q₄₈, the fifth output charge Q₅ may be a summation of the fifth-1 operation charge Q₅₁ to the fifth-8 operation charge Q₅₈, the sixth output charge Q₆ may be a summation of the sixth-1 operation charge Q₆₁ to the sixth-8 operation charge Q₆₈, and the seventh output charge Q₇ may be a summation of the seventh-1 operation charge Q₇₁ to the seventh-8 operation charge Q₇₈.

The bank 100 may provide the first output charge Q₁ to the seventh output charge Q₇ to the adder 40. The bank 100 may provide the first output charge Q₁ to the seventh output charge Q₇ to the adder 40 through the first output line BL₀₁ to the seventh output line BL₀₇.

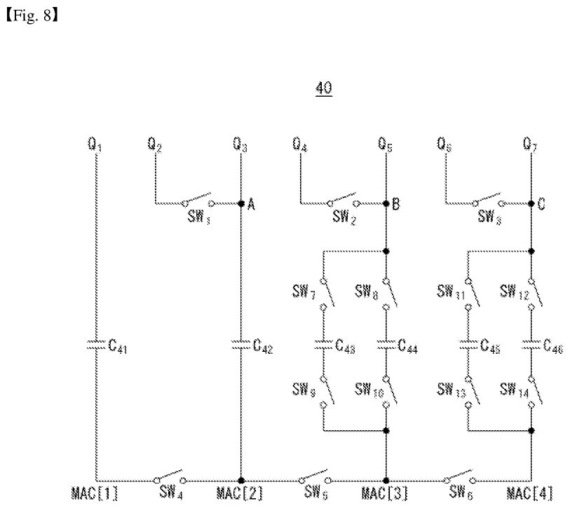

FIG. 8 is a circuit diagram illustrating the adder according to an embodiment of the present disclosure.

Referring to FIG. 8, the adder 40 according to an embodiment of the present disclosure may be provided with a plurality of output charges from the memory array 30. The adder 40 may be provided with the first output charge Q₁ to the seventh output charge Q₇ from each of the banks 31 to 38. The adder 40 may include a plurality of switches S_{W1} to S_{W14} and a plurality of capacitors C₄₁ to C₄₆. The adder 40 may control a plurality of switches S_{W1} to S_{W14} based on the weight precision bit number described in FIG. 7. The information for a signal that represents a weighting value sign is not required, but only a signal that represents a weighting value size is required in the weighting value operation. Accordingly, the adder 40 may control a plurality of switches S_{W1} to S_{W14} and a plurality of capacitors C₄₁ to C₄₆, based on the weight precision bit number as below and generate a first summation charge MAC [1] to a fourth summation charge MAC [4].

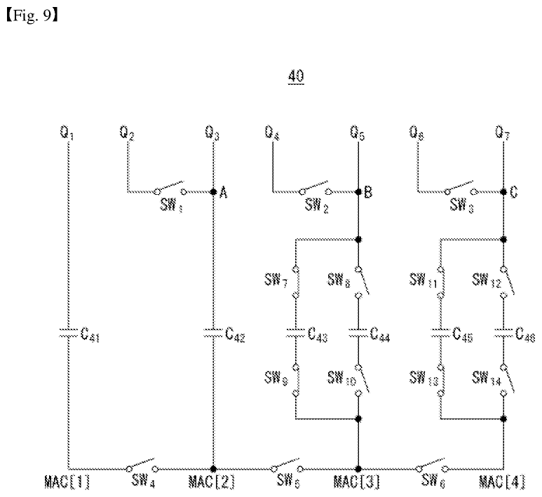

FIGS. 9 to 11 are circuit diagrams illustrating the adder according to the weight precision bit number.

FIG. 9 is a circuit diagram illustrating the adder 40 in the case that weight precision bit number is 2. Referring to FIG. 9, in the case that weight precision bit number is 2, the second output charge Q₂, the fourth output charge Q₄, and the sixth output charge Q₆ may represent a sign of a weighting value. The first output charge Q₁, the third output charge Q₃, the fifth output charge Q₅, and the seventh output charge Q₇ may be used for the weighting value operation. Accordingly, the adder 40 may open the first switch SW₁ to the sixth switch SW₆, the eighth switch SW₈, the tenth switch SW₁₀, the twelfth switch SW₁₂, and the fourteenth switch SW₁₄, and close the seventh switch SW₇, the ninth switch SW₉, the eleventh switch SW₁₁, and the thirteenth switch SW₁₃. In this case, each of the first summation charge MAC [1] to the fourth summation charge MAC [4] may be identical to the first output charge Q₁ to the fourth output charge Q₄.

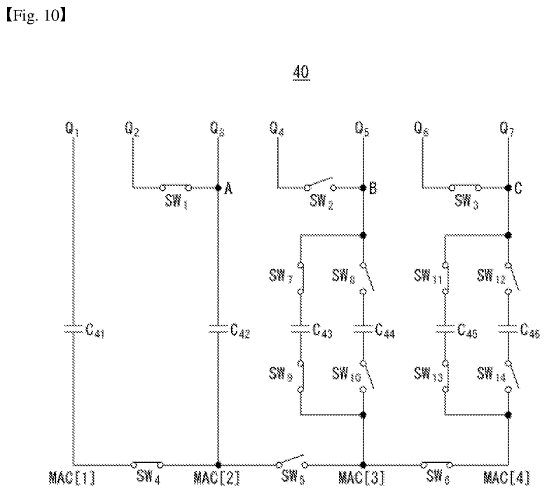

FIG. 10 is a circuit diagram illustrating the adder 40 in the case that weight precision bit number is 4. Referring to FIG. 10, in the case that weight precision bit number is 4, the fourth output charge Q₄ may represent a sign of a weighting value. The first output charge Q₁ to the third output charge Q₃ and the fifth output charge Q₅ to and the seventh output charge Q₇ may be used for the weighting value operation. Accordingly, the adder 40 may open the second switch SW₂, the fifth switch SW₅, the eighth switch SW₈, and the twelfth switch SW₁₂, and close the first switch SW₁, the third switch SW₃, the fourth switch SW₄, the sixth switch SW₆, the seventh switch SW₇, the ninth switch SW₉, the eleventh switch SW₁₁, and the thirteenth switch SW₁₃. The charge on the point A and the charge on the point C may be represented by Equation 1 and Equation 2 below.

$${Q}_{A} = \frac{2 {Q}_{2} + {Q}_{3}}{3} \qquad [ Equation 1 ]$$

In Equation 1, Q_{A} may be a charge on the point A.

$${Q}_{C} = \frac{2 {Q}_{6} + {Q}_{7}}{3} \qquad [ Equation 2 ]$$

In Equation 2, Q_{C} may be a charge on the point C.

The first summation charge MAC [1] may be the same as the second summation charge MAC [2] and may be represented by Equation 3 below.

$$M A C [ 1 ] = \frac{{C}_{41} {Q}_{0} + {C}_{42} {Q}_{A}}{{C}_{41} + {C}_{42}} \qquad [ Equation 3 ]$$

The third summation charge MAC [3] may be the same as the fourth summation charge MAC [4] and may be represented by Equation 4 below.

$$M A C [ 3 ] = \frac{{C}_{43} {Q}_{5} + {C}_{45} {Q}_{C}}{{C}_{43} + {C}_{45}} \qquad [ Equation 4 ]$$

The ratio of C₄₁:C₄₂ and C₄₃:C₄₅ may be 29:16.8.

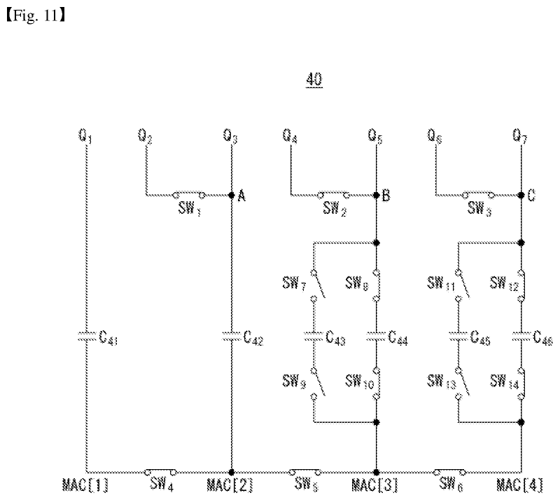

FIG. 11 is a circuit diagram illustrating the adder 40 in the case that weight precision bit number is 8. Referring to FIG. 11, the first summation capacitor C₄₁ may be the same as the third summation capacitor C43, and the second summation capacitor C₄₂ may be the same as the fifth summation capacitor C45.

Referring to FIG. 11, in the case that weight precision bit number is 8, the first output charge Q₁ to the seventh output charge Q₇ may be used for the weighting value operation. Accordingly, the adder 40 may open the seventh switch SW₇, the ninth switch SW₉, the eleventh switch SW₁₁, and the thirteenth switch SW₁₃, and close the first switch SW₁ to the sixth switch SW₆, the eighth switch SW₈, the tenth switch SW₁₀, the twelfth switch SW₁₂, and the fourteenth switch SW₁₄.

The charge on the point A, the charge on the point B, and the charge on the point C may be represented by Equation 5 to Equation 7 below.

$${Q}_{{A}^{′}} = \frac{2 {Q}_{2} + {Q}_{3}}{3} \qquad [ Equation 5 ]$$

In Equation 5, Q_{A′} may be a charge on the point A.

$${Q}_{{B}^{′}} = \frac{2 {Q}_{4} + {Q}_{5}}{3} \qquad [ Equation 6 ]$$

In Equation 6, Q_{B′} may be a charge on the point B.

$${Q}_{{C}^{′}} = \frac{2 {Q}_{6} + {Q}_{7}}{3} \qquad [ Equation 7 ]$$

In Equation 7, Q_{C′} may be a charge on the point C.

The third summation charge MAC [1] to the fourth summation charge MAC [4] may be the same and may be represented by Equation 8 below.

$$A C [ 0 ] = \frac{{C}_{41} {Q}_{1} + {C}_{42} {Q}_{{A}^{′}} + {C}_{44} {Q}_{{B}^{′}} + {C}_{46} {Q}_{{C}^{′}}}{{C}_{41} + {C}_{42} + {C}_{44} + {C}_{46}} \qquad [ Equation 8 ]$$

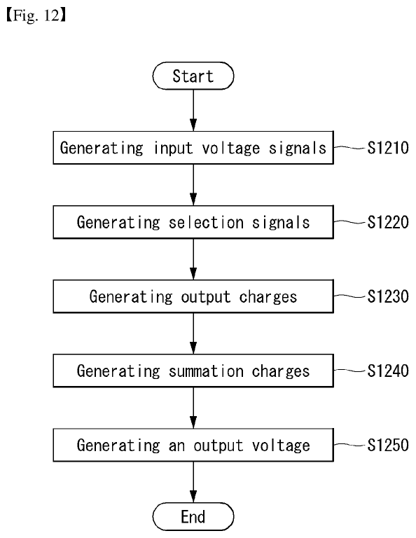

In this case, the ratio of C41:C42:C44:C46 may be 28:16.8:4:1. [0118] FIG. 12 is a flowchart illustrating an operation method of an in-memory computing apparatus according to an embodiment of the present disclosure.

Referring to FIG. 12, an in-memory computing apparatus may generate input voltage signals (step S1210). The in-memory computing apparatus may be provided with an input signal from the exterior. The in-memory computing apparatus may generate a first input voltage signal to a third input voltage signal based on the input signal. Here, the first input voltage signal may represent a sign of the input signal, the second input voltage signal may be opposite to that of the first input voltage signal, and the third input voltage signal may represent a magnitude of the input signal.

The in-memory computing apparatus may generate selection signals (step S1220). The in-memory computing apparatus may generate a first selection signal and a second selection signal. Here, the first selection signal and the second selection signal may be 2-bit signals and may be either one of [1, 0] or [0, 1].

The in-memory computing apparatus may generate output charges (step S1230).

The in-memory computing apparatus may determine a weight precision bit number based on the first selection signal and the second selection signal. For example, the weight precision bit number of the bank 100 may be one of 2, 4, and 8. The in-memory computing apparatus may control a circuit (e.g., the second memory cell 120) based on the weight precision bit number. The in-memory computing apparatus may generate output charges based on the first input voltage signal, the second input voltage signal, the first selection signal, and the second selection signal. For example, the output charges may include a first output charge to a seventh output charge.

The in-memory computing apparatus may generate summation charges (step S1240). The in-memory computing apparatus may control a circuit (e.g., the adder 40) based on the weight precision bit number. The in-memory computing apparatus may generate a summation charge by using at least one of the output charges. For example, the in-memory computing apparatus may generate a summation charge by using at least one of the first output charge to the seventh output charge.

The in-memory computing apparatus may generate an output voltage (step S1250). The in-memory computing apparatus may generate an analog voltage based on the summation charges. The in-memory computing apparatus may generate an output voltage by converting the analog voltage to a digital voltage.

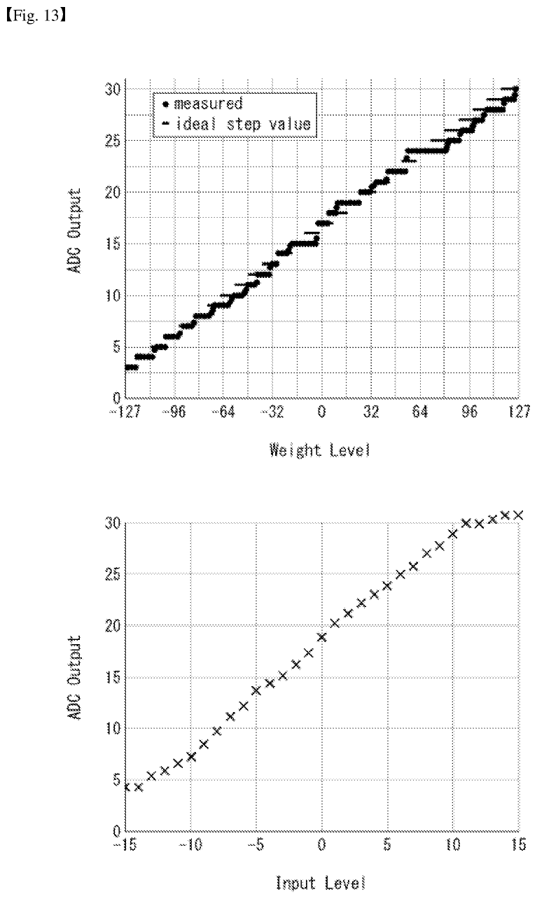

FIGS. 13 to 15 are conceptual diagrams illustrating the effect of the present disclosure.

FIG. 13 is a graph for which the performance is measured based on the in-memory computing apparatus designed in 28 nm FDSOI process. FIG. 13 shows a result of a measurement of an output voltage (ADC output) while a weighting value (weight level) and an input value (input level) are changed from a minimum value to a maximum value. The in-memory computing apparatus represents a linear weighting summation result. Since R square values in two cases are 0.9973 and 0.9922, respectively, which show linear results approximate to 1, it is identified that the results are close to ideal values.

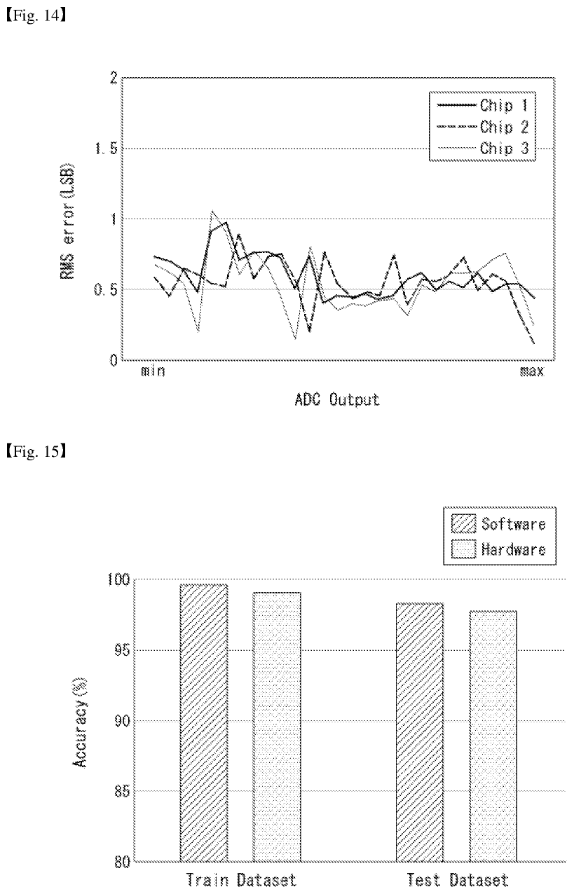

FIG. 14 shows a result in which a root mean square (RMS) error is measured in three different chip (chip 1 to chip 3). The error in each chip is measured while (1) an 8-bit weighting value is varied, (2) a 5-bit input value is varied, and (3) the activated number of weighting values are adjusted in a column, and the accurate average RMS values are 0.54, 0.55, and 0.59, respectively, which are very small values.

Table 3 below represents the amount of operation per time of the in-memory computing apparatus according to an embodiment of the present disclosure, and Table 4 represents the energy efficiency of the in-memory computing apparatus according to an embodiment of the present disclosure.

TABLE 3
Throughput (GOPS)

| Output | Min. Weight | Max. Weight |
|---|---|---|
| Bit Prec. | Precision (2-b) | Precision (8-b) |
| 2-b | 876.54 | 219.14 |
| 3-b | 701.24 | 175.31 |
| 4-b | 584.36 | 146.09 |
| 5-b | 500.88 | 125.22 |

TABLE 4
Energy Efficiency (TOPS/W)

| Output | Min. Weight | Max. Weight |
|---|---|---|
| Bit Prec. | Precision (2-b) | Precision (8-b) |
| 2-b | 119.38 | 32.28 |
| 3-b | 95.50 | 25.83 |
| 4-b | 79.58 | 21.52 |
| 5-b | 68.22 | 18.45 |

In Table 3 and Table 4, the throughput per time is represented in a giga (10⁹) unit, and the energy efficiency is represented in the number of operations performed per 1 watt per 1 second.

In the case that an output voltage (Output Bit Prec.) is 2-bit (2-b), and the weighting value bit number is 2-bit (2-b), 876.54*10⁹ operations may be performed per 1 second, and the energy efficiency may be 119.38*10¹². In the case that an output voltage (Output Bit Prec.) is 2-bit (2-b), and the weighting value bit number is 8-bit (8-b), 219.14*10⁹ operations may be performed per 1 second, and the energy efficiency may be 32.28*10¹².

In the case that an output voltage (Output Bit Prec.) is 3-bit (3-b), and the weighting value bit number is 2-bit (2-b), 701.24*10⁹ operations may be performed per 1 second, and the energy efficiency may be 25.83*10¹². In the case that an output voltage (Output Bit Prec.) is 3-bit (3-b), and the weighting value bit number is 8-bit (8-b), 175.31*10⁹ operations may be performed per 1 second, and the energy efficiency may be 25.83*10¹².

In the case that an output voltage (Output Bit Prec.) is 4-bit (4-b), and the weighting value bit number is 2-bit (2-b), 584.36.24*10⁹ operations may be performed per 1 second, and the energy efficiency may be 79.58*10¹². In the case that an output voltage (Output Bit Prec.) is 4-bit (4-b), and the weighting value bit number is 8-bit (8-b), 146.09*10⁹ operations may be performed per 1 second, and the energy efficiency may be 21.52*10¹².

In the case that an output voltage (Output Bit Prec.) is 5-bit (5-b), and the weighting value bit number is 2-bit (2-b), 500.88*10⁹ operations may be performed per 1 second, and the energy efficiency may be 68.22*10¹². In the case that an output voltage (Output Bit Prec.) is 5-bit (5-b), and the weighting value bit number is 8-bit (8-b), 125.22*10⁹ operations may be performed per 1 second, and the energy efficiency may be 18.45*10¹².

FIG. 15 is a graph for the result in which the accuracy of the in-memory computing apparatus according to an embodiment of the present disclosure is verified by using a MNIST data set. Here, for 60,000 learning data (Train Dataset), the accuracy (software) of neural network on a software operation is 99.71%, and the accuracy (hardware) of the in-memory computing apparatus according to an embodiment of the present disclosure is 97.74%. Accordingly, it is identified that the accuracy of the in-memory computing apparatus according to an embodiment of the present disclosure and the accuracy of neural network on a software operation are within 1% and fully accurate.

Although most terms used in the present disclosure have been selected from general ones widely used in the art, some terms have been arbitrarily selected by the applicant and their meanings are explained in detail in the following description as needed. Thus, the present disclosure should be understood based upon the intended meanings of the terms rather than their simple names or meanings.

It is apparent to those skilled in the art that the present disclosure may be embodied in other specific forms without departing from essential characteristics of the present disclosure. Accordingly, the aforementioned detailed description should not be construed as restrictive in all terms and should be exemplarily considered. The scope of the present disclosure should be determined by rational construing of the appended claims and all modifications within an equivalent scope of the present disclosure are included in the scope of the present disclosure.

What is claimed is:

1. An in-memory computing apparatus comprising:
an input controller provided with an input signal and configured to generate a first input voltage signal, a second input voltage signal, and a third input voltage signal based on the input signal;
a weighting value controller configured to generate a first selection signal and a second selection signal based on a weight precision bit number;
a memory array provided with the first input voltage signal, the second input voltage signal, and the third input voltage signal from the input controller, and provided with the first selection signal and the second selection signal from the weighting value controller, and configured to generate a first output charge to a seventh output charge based on the first input voltage signal, the second input voltage signal, the third input voltage signal, the first selection signal, and the second selection signal; and
an adder provided with the first output charge to the seventh output charge from the memory array and configured to generate a first summation charge to a fourth summation charge based on the weight precision bit number and the first output charge to the seventh output charge.

2. The in-memory computing apparatus of claim 1, wherein the memory array includes banks in which first memory cells are arranged in a first column and second memory cells are arranged in a second column to a fourth column.

3. The in-memory computing apparatus of claim 2, wherein the first memory cells arranged in the first column generate first operation charges, the second memory cells arranged in the second column generate second operation charges and third operation charges, the second memory cells arranged in the third column generate fourth operation charges and fifth operation charges, and the second memory cells arranged in the fourth column generate sixth operation charges and seventh operation charges, and
wherein each of the first output charge to the seventh output charge is a summation of the first operation charges to a summation of the seventh operation charges.

4. The in-memory computing apparatus of claim 1, wherein the first summation charge is identical to the second summation charge based on the weight precision bit number being 4.

5. The in-memory computing apparatus of claim 4, wherein the adder generates the first summation charge and the second summation charge based on the first output charge to the fourth output charge.

6. The in-memory computing apparatus of claim 1, wherein the first summation charge is identical to the fourth summation charge based on the weight precision bit number being 8.

7. The in-memory computing apparatus of claim 6, wherein the adder generates the first summation charge and the fourth summation charge based on the first output charge to the seventh output charge.

8. The in-memory computing apparatus of claim 1, further comprising an output controller provided with the first summation charge and the fourth summation charge and configure to generate an output voltage.

9. The in-memory computing apparatus of claim 8, wherein the output controller is configured to generate an analog voltage based on the first summation charge and the fourth summation charge, and generate the output voltage by converting the analog voltage to a digital voltage.

10. A method for operating an in-memory computing apparatus, comprising:
generating a first input voltage signal, a second input voltage signal, and a third input voltage signal based on an input signal;
generating a first selection signal and a second selection signal based on a weight precision bit number;
generating a first output charge to a seventh output charge based on the first input voltage signal, the second input voltage signal, the third input voltage signal, the first selection signal, and the second selection signal; and
generating a first summation charge to a fourth summation charge based on the first output charge to the seventh output charge and the weight precision bit number.

11. The method for operating an in-memory computing apparatus of claim 10, wherein the first summation charge is identical to the second summation charge based on the weight precision bit number being 4.

12. The method for operating an in-memory computing apparatus of claim 11, further comprising generating the first summation charge and the second summation charge based on the first output charge to the fourth output charge.

13. The method for operating an in-memory computing apparatus of claim 10, wherein the first summation charge is identical to the fourth summation charge based on the weight precision bit number being 8.

14. The method for operating an in-memory computing apparatus of claim 13, further comprising generating the first summation charge and the fourth summation charge based on the first output charge to the seventh output charge.

15. The method for operating an in-memory computing apparatus of claim 10, further comprising generating an output voltage based on the first summation charge and the fourth summation charge.

16. The method for operating an in-memory computing apparatus of claim 15, wherein generating the output voltage includes:
generating an analog voltage based on the first summation charge and the fourth summation charge; and
converting the analog voltage to a digital voltage.

17. A memory array comprising:
first memory cells arranged in a first column and provided with a first input voltage signal, a second input voltage signal, and a third input voltage signal to generate a first output charge; and
second memory cells arranged in a second column to a fourth column and provided with the first input voltage signal, the second input voltage signal, the third input voltage signal, a first weighting value selection signal, and a second weighting value selection signal to generate a second output charge to a seventh output charge,
wherein the first memory cell includes a first static random access memory (SRAM) for storing a sign of a weighting value and a second SRAM for storing a size of the weighting value, and
wherein the second memory cell includes a third SRAM for storing either one of a sign or a size of the weighting value and a fourth SRAM for storing a size of the weighting value.

18. The memory array of claim 17, wherein the first memory cells generate a sign signal based on the first input voltage signal and the sign of the weighting value.

19. The memory array of claim 18, wherein,
a first threshold voltage signal is applied to the first memory cells, and
the first memory cells generate a sampling signal based on the third input voltage signal and the sign signal.

20. The memory array of claim 19, wherein the first memory cells generate a first operation charge based on the sampling signal.

21. The memory array of claim 19, wherein,
a second threshold voltage signal is applied to the second memory cells, and
the second memory cells generate a first operation charge based on the second threshold voltage signal.

22. The memory array of claim 17, wherein the second memory cells further include a first capacitor and a second capacitor, and
wherein a size of the first capacitor is double a size of the second capacitor.
